(19) United States
(12) Patent Application Publication
(10) Pub. No.: US 2025/0379027 A1
(43) Pub. Date: Dec. 11, 2025

(54) Plasma Electron Beam Installation System

(71) Applicant: Elena Avram, Hanover, MD (US)

(72) Inventor: Elena Avram, Hanover, MD (US)

(21) Appl. No.: 19/062,487

(22) Filed: Feb. 25, 2025

Related U.S. Application Data
(60) Provisional application No. 63/658,467, filed on Jun. 11, 2024.

(51) Int. Cl. H01J 37/305; H01J 37/077

(52) U.S. Cl. CPC H01J 37/305; H01J 37/077; H01J 2201/19

(57) ABSTRACT

The present invention is a High-Power Plasma Electron Beam Installation (HPPEBI) system. The system comprises a cathode configured to generate high-energy electron beams within a vacuum chamber, an anode to stabilize the plasma, wherein the focus of the electron beam is based on cathode geometry, enabling cylindrical, circular, point, or linear configurations. The electron beam delivers energy directly to the target material, inducing localized heating, melting, evaporation, or structural modifications with minimal impact on surrounding areas. The system facilitates precise and efficient processes, such as phase transformations, thin film deposition, and defect creation, enhancing material properties. Cooling mechanisms integrated with the cathode and anode prevent overheating during high-energy operations.

### CROSS-REFERENCE TO RELATED APPLICATION

The present application claims priority to, and the benefit of, U.S. Provisional Application No. 63/658,467 which was filed on Jun. 11, 2024, and is incorporated herein by reference in its entirety.

### FIELD OF THE INVENTION

The present invention generally relates to advanced material processing systems. More specifically, the invention relates to a High-Power Plasma Electron Beam Installation (HPPEBI) system designed to enhance precision and efficiency in melting-casting technologies of hard fusible alloys, ultra-fast heat treatments of steels and alloys (hardening, annealing, tempering, texturing, and polishing), “single shot” welding of different metals, alloys, insulators and thin layer deposition (ALD). The system generates, within a vacuum chamber, plasma and high-energy electron beams with a monoenergetic distribution, using configurable cathodes to deliver tailored heating profiles, such as cylindrical, circular, point, or linear focus. Thin or broad electron beams, converging or diverging, can be designed over a wide range of current and voltage. These electron beams transfer energy directly to target materials with a high efficiency (minimum 80%), enabling localized heating, melting, evaporation and selective surface structural modification without affecting the bulk of the material, with minimal distortion or residual stress. Accordingly, the present disclosure makes specific reference thereto. Nonetheless, it is to be appreciated that aspects of the present invention are also equally applicable to others like applications, devices, and methods of manufacture.

### BACKGROUND

In different industrial applications, the performance, longevity, and effectiveness of materials rely heavily on the accuracy and effectiveness of their surface treatment processes. Due to the reduction of natural resources and continuous growth of modern industry, the involvement of new technologies for the manufacturing of materials, as well as for modification of their structure and properties, is of major importance. Since the mid-20th century, the traditional (i.e., conventional) thermionic electron gun system has served as the foundation for numerous specialized surface treatment applications, such as hardening, annealing, tempering, texturing, and polishing, welding, and coating deposition. One object of the present disclosure is the use of High-Power Plasma Electron Beams Installation (HPPEBI) system which is an improvement from the Thermionic Electron Gun system. The power density of electrons generated in HPPEBI system is typically higher than that of electrons generated in a Thermionic Electron Gun due to several key differences in their mechanisms and operating principles. HPPEBI provides a vacuum chamber at a low vacuum 10⁻¹ torr and a plasma is generated by applying a high voltage (>10 kV) on electrodes (i.e., cathode and anode). The important components of plasma are electrons, ions and atoms. Electrons emitted by cathode are accelerated by plasma electric field reaching high energy corresponding to the high voltage applied. Also, electron number increases during the heat treatment process due to the frequent collisions in plasma. Thermionic electron gun provides for an electron beam generated by a thermionics emission (the free electrons emitted by the filament cathode) in a high vacuum 10⁻⁷ torr, needs an electric field to be accelerated and a magnetic field to be focused on a workpiece. Energy distribution is largely governed by the cathode temperature and follows the Maxwell-Boltzmann distribution, which limits the average electron energy. The kinetic energy of the free electron beam is transformed into thermal energy at the surface of the workpiece. This is typically lower than the energy achievable in High-Power Plasma Electron Beams (HPPEB) systems. Also, the electron density is limited by the material properties of the cathode and the maximum achievable temperature before material degradation. In HPPEBI, electrons emitted by the cathode are accelerated in the plasma electric field. This controlled acceleration results in a narrow energy distribution for the electrons, as they all gain energy primarily from the same electric field. Thermionic Electron Gun electrons are emitted from a heated filament cathode due to thermal excitation, which follows the Maxwell-Boltzmann energy distribution, a broad energy distribution. As a result, the thermionic gun relying on thermal processes inherently produce a wide range of electron energies. One fundamental law of HPPEB mechanism is that the electrons are emitted perpendicularly on the cathode surface, are accelerated by the plasma electric field and the focus is not influenced by the discharge parameters. System generates a high-energy, monoenergetic electron beam with a focus determined by the cathode geometry only. In the HPPEB system there is no need for additional electric and magnetic fields to focus on the electron beam. In Thermionic Electron Gun applications the electrons emitted from the heated filament diverge significantly as they travel toward the target, contributing to a broader impact zone with the target. The electron beam is harder to focus sharply due to limitations in the electron optics, such as the cathode size, beam divergence, and space charge effects. Broader heating zones can cause more thermal distortion and thermal stress in the target, making it less ideal for precision applications. Thermal distortion is critical for components requiring tight tolerances. In all applications, the Thermionic Electron Gun needs two or more additional electric and magnetic fields to focus the electron beam on the target. With HPPEBI the electron beams transfer energy directly to target materials with a minimum efficiency of 80%, thereby enabling localized heating, melting, evaporation, and structural modifications without affecting the bulk of the material. Efficient energy transfer increases the speed and effectiveness of heat treatment. Thermionic Electron Gun applications are less efficient in energy transfer due to limitations in electron emission and beam focusing. The filament has a max limit for emitted electrons and the electron focus is changing with power and pressure. HPPEBI generates a powerful electron beam with different configurations, and different thermal profiles (i.e., circular, punctual, cylindrical, and linear) which can be used in different heat treatment technologies. The spatial distribution of electrons is determined only by the cathode and anode geometries. In contrast, Thermionic Electron Gun applications generate an electron beam with a point focus. It is used only for certain heat treatment technologies which need a point focalization. For example, in heat treatment technologies used for complex tool configurations. In HPPEBI, the electron beam interacts with the workpiece, inducing a variety of effects that can be harnessed for high-precision treatment technologies. When high-energy, focused electrons collide with atoms in the target material, they cause selective surface modification without affecting the bulk of the material such as heating, melting, evaporation, ionization, and phase changes (i.e., convert materials from amorphous to crystalline states). The beam can be tightly focused, thereby enabling nanoscale precision in material removal or addition, crucial for applications in nanotechnologies. The high-energy electron beam can also displace atoms within a solid, altering the properties of materials, where controlled defect creation can improve strength, conductivity, or durability. This capability makes electron beams ideal for thin-film deposition and microfabrication in industries like semiconductors and electronics. This capability is crucial in industries like aerospace and automotive, where specific material properties such as hardness, corrosion resistance, or thermal stability can be enhanced through these transformations. In contrast, Thermionic Electron Gun applications deliver significantly lower electron energy density in the target, it fails to achieve controlled heating at deeper levels, potentially leaving subsurface residual stresses untreated. The broad energy spectrum results in varied penetration depths and contribute to a more diffuse interaction with the target. Inefficient heat treatment processes lead to inadequate microstructural refinement, and reduced fatigue strength. The cathode of HPPEBI generates high energy electron beams, with any configuration in space and time. Thus, the heat treatment technology can be accomplished in a single shot providing for a uniform finish over the entire workpiece surface. On the other hand, Thermionic Electron Gun applications generate an electron beam with a point focus. Thus, for complex workpiece configurations, it is necessary to accommodate many thermionic electron guns in the same vacuum chamber. Alternatively, the workpiece and/or Thermionic Electron Gun can be rotated during the heat treatment to cover the entire workpiece surface, causing uneven heating, distortion, warping of the workpiece. HPPEBI applications are suitable for a wider range of materials and treatment techniques. The suitability for processing any kind of material (metal, alloys, dielectric, glass, ceramic, isolator) is enabled because the plasma doesn't allow the build-up charging effect. The build-up charging effect refers to the accumulation of electrical charge on the surface or within a material due to the interaction with electrons. In the insulating or poorly conducting materials the first electrons that reach the target remain in the target structure and reject the other electrons that come. But plasma, which surrounds the entire workpiece, will neutralize the accumulated charge. Thermionic Electron Gun applications are often limited to specific materials and applications. The conventional electron gun can't be used for dielectric, isolating materials because the first electrons that reach the target remain in the structure of the target and reject the other electrons that come. HPPEBI can generate much higher temperatures, making it suitable for treating materials with high melting points, such as refractory metals and advanced alloys. In contrast, Thermionic Electron Gun applications limit a maximum temperature that can be achieved, thereby restricting its use for high-temperature applications. The electron density is limited by the material properties of the filament cathode and the maximum achievable temperature before material degradation. HPPEBI applications provide a combination of higher power density, efficient energy transfer, and one-shot processes, enabling HPPEB to process materials more quickly, leading to shorter production cycles and increased productivity. Thermionic Electron Gun applications provide slower production cycles due to lower energy density and less efficient heat transfer. HPPEBI reduces operational costs due to the simple system configuration, soft vacuum (10⁻¹ torr), and faster processing cycles. Thermionic Electron Gun result in higher expenses with the consumable filament materials, complicated thermionic electron gun configuration including the additional electric and magnetic fields and pumps necessary for the high vacuum (10⁻⁶ torr). HPPEBI, along with the plasma process, distinguishes itself using materials which are environmentally friendly. No toxic by-products are produced that would otherwise have to be disposed of at incalculable costs. Plasma and electron beam operate in a vacuum or controlled atmosphere, preventing contamination and oxidation of the treated surface. This ensures higher-quality results, particularly in applications requiring pristine surface conditions, thereby generating less heat and waste, making them more environmentally friendly for industrial use. Thermionic Electron Gun (TEG) applications are generally less clean and have fewer environmental benefits. TEG needs higher energy consumption, a high-vacuum environment to operate efficiently, and release contaminants from filament material (i.e., tungsten, LaB₆, or BaO) leading to environmental impacts. Resultant surface oxidation and impurities may require post-processing. HPPEBI provides high precision and localized heating thereby minimizing thermal gradients, thermal distortion, and reducing the risk of thermal stress and cracking in the treated materials. This is critical for components requiring tight tolerances. TEG has broader heating zones which can cause more thermal distortion, making it less ideal for precision applications. The energy density of the thermionic electron beam is lower and spread out. This is suitable for applications where a broader heating area is required but is less effective for precise or high-intensity applications. HPPEBI systems are scalable for various applications, from microelectronics to large-scale industrial components, making them more versatile for different heat treatment technologies. TEG is typically used in the heat treatment technologies where it is necessary for a point focalization and low energy. Beam control is less versatile, which can limit its applicability for intricate or highly specific treatments. Summarily, using HPPEBI instead of TEG in the heat treatment technologies helps avoid or minimize thermal stress, mechanical stress, and residual stress. HPPEBI delivers energy and heat more precisely and quickly to the target. This localized heating minimizes thermal gradients and heat-affected zones, thereby reducing the risk of warping or cracking. Also, the faster processing time of HPPEB reduces prolonged thermal exposure, lowering the likelihood of thermal fatigue. TEG delivers broad energy and heat spectrum to the target in longer time causing warping, cracking, and thermal fatigue, especially in materials with low thermal conductivity or high thermal expansion coefficients. HPPEBI provides for localized and controlled heat input resulting in more uniform heating and cooling, significantly reducing residual stress formation. TEG systems can induce residual stress as the material cools unevenly, especially near welds, joints, or treated surfaces. These stresses can compromise structural integrity and lead to fatigue failure over time. HPPEBI can effectively remelt and seal defects such as micro-cracks and pores, homogenizing the material and reducing stress concentration points. TEG includes lower beam intensity and broader energy distribution require longer exposure times, leading to mechanical distortion or deformation, especially in thin or delicate components. HPPEBI produces a much smaller Heat Affected Zone (HAZ) due to their concentrated energy delivery, thereby preserving the microstructure of the surrounding material and avoiding unwanted phase transformations. TEG has a larger HAZ produced by thermionic electron guns which can lead to grain growth, phase changes, or hardening/softening in unintended regions, introducing stress or brittleness. HPPEBI provides precision of heat treatment technology thereby ensuring uniform material property changes, such as hardness or composition and avoiding internal stress gradients. The uniform heating of the entire workpiece by the surrounding plasma reduces significant distortion and warping. TEG includes non-uniform heating which can create localized variations in material properties, such as hardness or tensile strength, leading to stresses when the workpiece is subjected to operational loads. Inefficient heat treatment processes lead to inadequate microstructural refinement, resulting in reduced fatigue strength. HPPEBI provides for faster work due to higher energy densities, significantly reducing the overall processing time and limiting stress accumulation. TEG includes longer exposure times resulting in cumulative thermal and mechanical effects, increasing stress in the material. HPPEBI comprising plasma surrounding the workpiece ensures uniform heating and annealing of complex workpiece geometries, ensuring thorough stress relief. TEG includes uneven energy delivery of thermionic guns which can leave behind unrelieved stresses, particularly in treated areas with complex geometries. Many existing patents focus either on electron beam treatment or plasma treatment independently. The present disclosure uniquely combines both technologies, allowing for more precise control over the heat treatment process, which can enhance surface properties and reduce defects. By integrating both electron beam and plasma technologies, the HPPEBI system eliminates cracking and failure during service. The combined effect of electron beam and plasma can significantly enhance surface properties such as hardness, wear resistance, corrosion resistance, reduction of energy consumption, processing time and residual stresses. The aforementioned dual approach enables a more controlled modification of the microstructure, leading to superior performance of treated components. Individuals desire high power plasma electron beam technology that enhances surface properties, reduces processing times, and accommodates complex geometries with minimal distortion or residual stress.

Therefore, there exists a long-felt need in the art for a system that can address the limitations of traditional heat treatment processes. Specifically, there is a long-felt need for a system that can deliver precise and localized heating to improve material properties without introducing distortion or residual stress. Furthermore, there is a long-felt need for a system that can process components with complex geometries while maintaining uniform treatment. Additionally, there is a need for an efficient heat treatment system that reduces processing times and energy consumption. Moreover, there is a long-felt need in the art for a system that produces different thermal profiles, such as circular, linear, and pinpoint, for precise and customizable heat distribution. Finally, there is a need for a versatile material processing system that can integrate seamlessly into existing manufacturing workflows or be customized for advanced applications such as thin film deposition, welding, and additive manufacturing.

The subject matter disclosed and claimed herein, in one embodiment, comprises a High-Power Plasma Electron Beam Installation (HPPEBI) system designed to address the challenges of traditional heat treatment methods. The system generates plasma and uniform, high-energy electron beams within a vacuum chamber using different cathode-anode configurations. The cathodes are configurable to produce electron beams with cylindrical, circular, point, or linear focus, providing precise and customizable heating profiles. The system includes cooling systems for thermal management during high-energy operations. The electron beams transfer energy directly to the target material, enabling localized heating, melting, evaporation, or structural modification. Applications include melting-casting technologies of hard fusible alloys, ultra-fast heat treatments of steels and alloys (hardening, annealing, tempering, texturing, and polishing), “single shot” welding of different metals, alloys, insulators and thin layer deposition (ALD).

In this manner, the High-Power Plasma Electron Beam Installation (HPPEBI) system of the present invention fulfills the aforementioned needs by providing an innovative, efficient, and versatile solution for new heat treatment technologies and manufacturing new materials with unique functional properties. HPPEBI system is unique because combines the high energy density of electron beams with the thermal properties of plasma, leading to enhanced surface properties, such as increased hardness, wear resistance, and corrosion resistance.

HPPEBI is a groundbreaking technology that has the potential to revolutionize industrial processes across various sectors: melting-casting technologies of hard fusible alloys, ultra-fast surface heat treatments of steels and alloys (hardening, annealing, tempering, texturing, and polishing), single-shot welding of different metals, alloys, insulators and thin layer deposition (ALD). This new technology becomes indispensable for industries such as aerospace, automotive, semiconductors, biomedical and advanced manufacturing. In conclusion, HPPEB offers practical, technical, and economic advantages for a wide range of technologies due to the following: generating a very powerful electron beam with different configurations, and different thermal profiles (circular, pinpoint, cylindrical and linear); and, processing any kind of material (metal, alloys, dielectric, glass, ceramic, isolator); reducing significant warping, distortion, failure in service and residual stress because electron beam delivers high energy density in one shot, with a certain profile ensuring a limited heat spread zone, with a rapid local heating/cooling and low thermal gradient between treated and untreated areas. Also, the electron beam alters the workpiece surface properties without physically removing material, thereby preserving the overall structure. Heat treatment technology can be done in a single shot completely with no need to rotate or move the workpiece or the electron source during the heat treatment. The innovative HPPEBI offers unparalleled precision, energy efficiency, and reduced operational costs, making it far superior compared with conventional methods like Thermionic Electron Gun.

### SUMMARY OF THE INVENTION

The following presents a simplified summary in order to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises a high-power plasma electron beam installation for melting and casting processes. The installation comprises a spherical cap cathode configured to generate high-power electron beams with a circular focus, a crucible is integrated to contain a metal material, wherein the electron beams focus on the crucible to deliver high energy for melting the metal material, and an additional anode located at a certain distance from the cathode, shielding the passive surface of the cathode.

Another additional metal electrode with a floating potential mounted at a certain distance from the cathode, d, is maintaining the plasma only to the region crossed by the fast electron beams, increases the electron source efficiency over 85%. This invention uses a diaphragm fixed at the level of the electron beam focus with the help of metal rods to protect the cathode surface from the action of the metal vapors and drops released by the overheated target. The additional metal electrode could have various heights, being made of several annular segments and the lateral surface has the observation holes for different plasma measurements. This second metal electrode is configured for higher energy operations and coupled with a water-cooling system, and wherein the melted metal material in the crucible is poured into molds to form components.

In another aspect, a high-power plasma electron beam installation for thin film deposition processes is disclosed. The installation includes a cathode adapted to generate a high-energy electron beam, a crucible is positioned within a vacuum chamber to hold a metal material, wherein the electron beam heats and evaporates the metal to create a vapor, introducing at least one gas into the vacuum chamber, enabling the vaporized metal to interact and form thin films on a target surface, and wherein the thin films are deposited with specific compositions for applications including solar panels, semiconductors, and optical devices.

In one embodiment, a high-power plasma electron beam installation for circular welding is disclosed. The installation includes a doughnut-shaped (i.e., curvilinear) cathode adapted to generate focused electron beams aligned with circular ends of workpieces, an anode is configured to confine plasma generated during the welding process, wherein the electron beams deliver energy to the circular ends of the workpieces, enabling melting and fusion to form strong circular welds in a single operation.

In yet another aspect, a high-power plasma electron beam installation for material processing is disclosed. The installation includes a cathode configured to generate high-energy electron beams with configurable beam shapes based on cathode geometry, wherein the cathode geometry includes a rectangular section for cylindrical heating focus, a doughnut shape for circular focus, a spherical cap for point focus, and a rectangular prism for linear focus.

In still another embodiment, a high-power plasma electron beam installation for phase transformation processes is disclosed. The installation includes a cathode configured to generate a high-energy electron beam directed towards a target material, a vacuum chamber containing the target material and the cathode, wherein the electron beam induces localized phase transformations in the target material, wherein the electron beam modifies the crystalline structure of the target material, converting amorphous materials to crystalline states or inducing transitions between crystal structures to enhance hardness, thermal stability, or corrosion resistance.

In still another aspect, a high-power plasma electron beam installation for material processing is disclosed. The installation includes a cathode configured to generate a high-energy electron beam within a vacuum chamber, an anode is positioned to confine plasma and stabilize the electron beam during operation, a target holder is configured to secure a workpiece within the vacuum chamber, the cathode geometry defines the beam focus as one of a cylindrical, circular, point, or linear configuration, wherein the electron beam interacts with the target material to induce localized heating, melting, evaporation, or structural modification, enabling processes including but not limited to melting, casting, thin film deposition, welding, additive manufacturing, surface treatment, or phase transformations.

Numerous benefits and advantages of this invention will become apparent to those skilled in the art to which it pertains upon reading and understanding of the following detailed specification.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective view of High Power Plasma Electron Beam Installation (HPPEBI) system of the present invention for melting/casting and thin film deposition in accordance with the disclosed architecture;

FIG. 2 illustrates a perspective view showing the HPPEBI system for circular welding in accordance with one embodiment of the present invention;

FIG. 3 illustrates a schematic view of High-Power Plasma Electron Beam Installation (HPPEBI) system in accordance with the disclosed structure;

FIG. 4 illustrates a flow chart depicting a process of making structural changes in a target material using electron beam in accordance with one embodiment of the present invention;

FIG. 5A illustrates an exemplary HPPEBI system with a rectangular cathode in accordance with the disclosed structure;

FIG. 5B illustrates another HPPEBI system with a doughnut-shaped (i.e., curvilinear) cathode in accordance with the disclosed structure;

FIG. 5C illustrates another embodiment of the HPPEBI system in accordance with the disclosed structure;

FIG. 5D illustrates the HPPEBI system with rectangular prism cathode in accordance with the disclosed structure; and

FIG. 6 illustrates yet another embodiment of HPPEBI system for thin film deposition in accordance with the disclosed structure.

### DETAILED DESCRIPTION OF THE PRESENT INVENTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there exists a long-felt need in the art for a system that can address the limitations of traditional heat treatment processes. Specifically, there is a long-felt need for a system that can deliver precise and localized heating to improve material properties without introducing distortion or residual stress. Furthermore, there is a long-felt need for a system that can process components with complex geometries while maintaining uniform treatment. Additionally, there is a need for an efficient heat treatment system that reduces processing times and energy consumption. Moreover, there is a long-felt need in the art for a system that produces different thermal profiles, such as circular, linear, and pinpoint, for precise and customizable heat distribution. Finally, there is a need for a versatile material processing system that can integrate seamlessly into existing manufacturing workflows or be customized for advanced applications such as melting-casting technologies of hard fusible alloys, ultra-fast heat treatments of steels and alloys (hardening, annealing, tempering, texturing, and polishing), “single shot” welding of different metals, alloys, insulators and thin layer deposition and additive manufacturing.

The present invention, in one exemplary embodiment, is a high-power plasma electron beam installation for material processing. The installation includes a cathode configured to generate a high-energy electron beam within a vacuum chamber, an anode is positioned to confine plasma and stabilize the electron beam during operation, a target holder is configured to secure a workpiece within the vacuum chamber, the cathode geometry defines the beam focus as one of a cylindrical, circular, point, or linear configuration, wherein the electron beam interacts with the target material to induce localized heating, melting, evaporation, or structural modification, enabling processes including but not limited to melting, casting, thin film deposition, welding, additive manufacturing, surface treatment, or phase transformations.

Reference will now be made in detail to the present preferred embodiments of the invention, examples of which are illustrated in the accompanying drawings. Wherever possible, the same reference numerals are used in the drawings and the description to refer to the same or like parts.

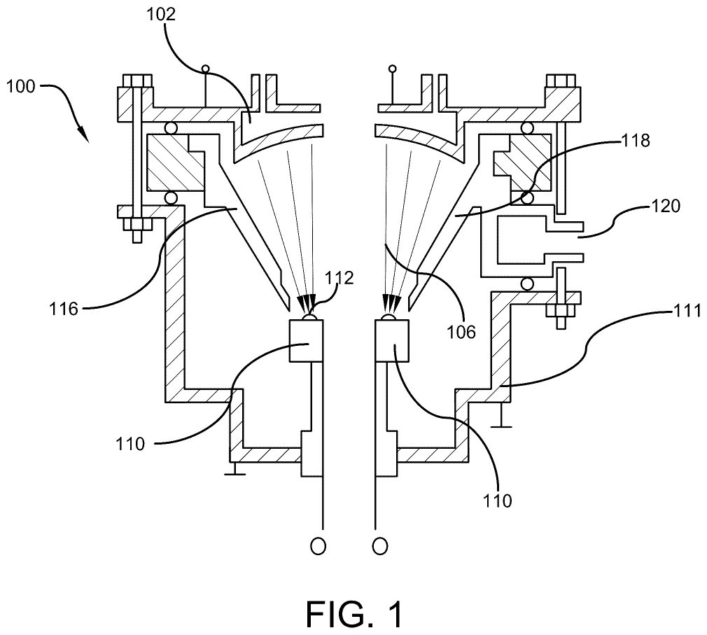

Referring initially to the drawings, FIG. 1 illustrates a perspective view of High Power Plasma Electron Beam Installation (HPPEBI) system of the present invention for melting/casting and thin film deposition in accordance with the disclosed architecture. The HPPEBI system 100 of the present embodiment is designed for melting, casting, and thin film deposition processes. System 100 includes a spherical cap cathode 102 for generating the high-power electron beam 106. The spherical cap cathode 102 enables a circular focus of the corresponding electron beam 106, which provides localized heating and precise control of the melting and evaporation processes.

The electron beam 106 generated by the cathode member 102 focus on a metal integrated crucible 110 and deliver high energy to melt or evaporate metals placed in the crucible 110. The crucible 110 contains the metal to be melted or evaporated and the metal portions are heated until the portions melted and are poured into molds to form new components. For thin film deposition, the metal evaporates, creates a vapor that interacts with gases in the vacuum chamber 111 to form thin films on a target.

As illustrated, melted metal portions 112 result from the focused electron beam's energy and the melted metal portions 112 are in liquid form and are transferred into molds. The system includes a first anode 116 without cooling water which shields the passive surface of the cathode. A second anode 118 is configured with a cooling water source 120 and is used to confine plasma to the electron beam area and increase the process efficiency.

In use, system 100 is used for melting and casting wherein the electron beam 106 focus on the metal in the crucible to rapidly heat the metal to its melting point. Once melted, the liquid metal can be poured into a mold or form (not shown in the illustration) to create new tools or components and the system 100 can be used in industries like aerospace, automotive, and manufacturing, where precision casting is required.

For thin film deposition, the electron beam 106 evaporates the metal in the crucible 110 and the evaporated metal interacts with gases in a vacuum chamber to form thin films with specific compositions on a target surface. Thin films can be used in forming solar panels, optical devices, semiconductors, and more.

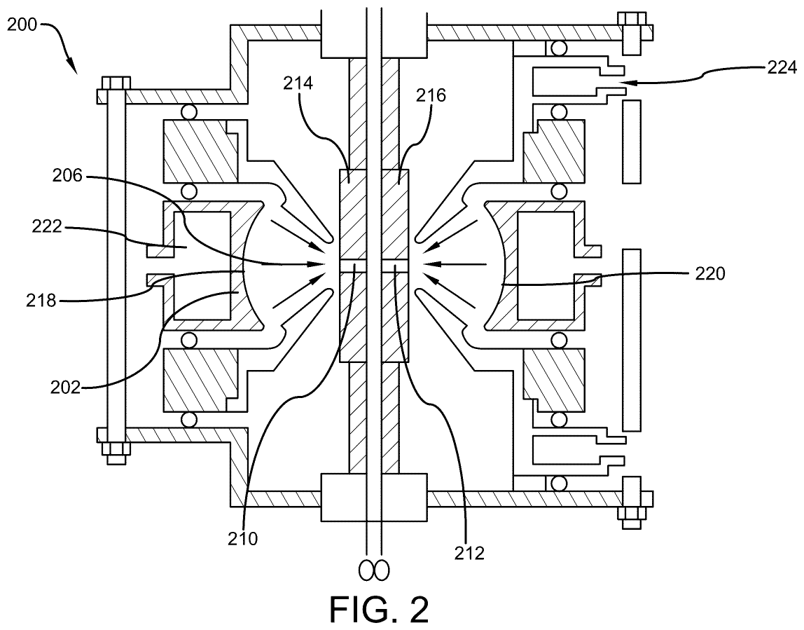

FIG. 2 illustrates a perspective view showing the HPPEBI system for circular welding in accordance with one embodiment of the present invention. The circular welding HPPEBI system 200 includes a doughnut shaped cathode 202 wherein the cathode is adapted to generate a focused electron beam upon the application of high voltage. As illustrated, the cathode 202 generates the electronic beam 206. The doughnut shape of the cathode enables focus of the electron beam align with the welded ends 210, 212 of the workpiece pipes 214, 216, thereby enabling precise and uniform heating.

The electron beam 206 is directed perpendicularly (i.e., orthogonally) to the corresponding cathode surface 202. The workpiece pipes 214, 216 are welded at circular zones at the ends 210, 212 respectively. The circular zones 210, 212 receive the energy of the electron beam and the zones 210, 212 melt and fuse, creating a strong and effective circular weld. Anodes are positioned to limit the plasma, preventing the plasma from interfering with the vacuum chamber. The first water cooling system 222 is coupled to the cathode 202 and a second water cooling system 224 is coupled to the anode 218 or 220 to prevent overheating during high-energy operations.

The system 200 completes the welding in a single operation without requiring movement of the workpieces or electron beam. Further, the cathode 202 provides perfect alignment of the electron beam 206 with the circular pipe ends 210, 212, providing consistent weld quality. The system 200 is useful for pipe welding used in industries such as pipelines, aerospace, and automotive sectors.

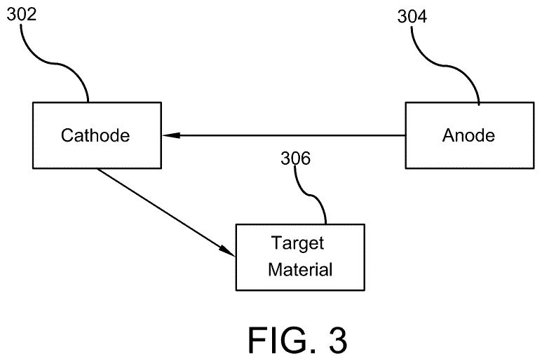

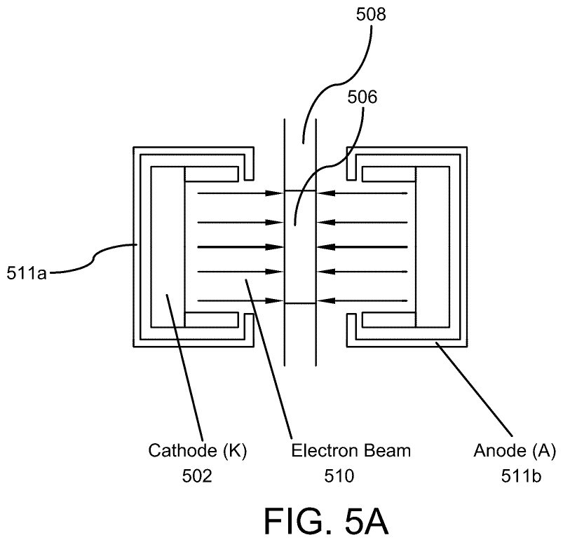

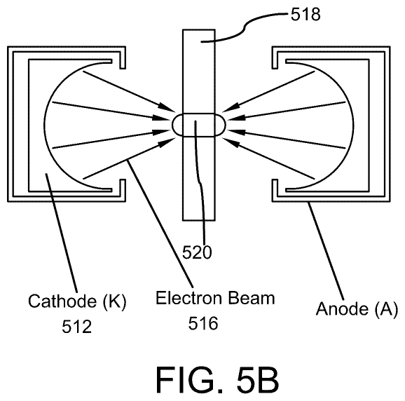

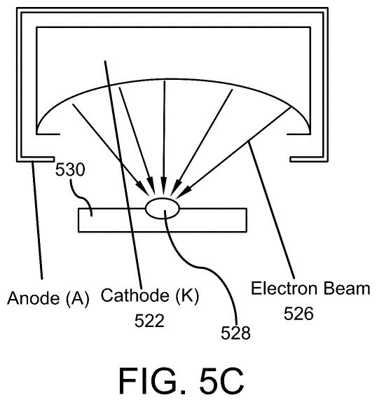

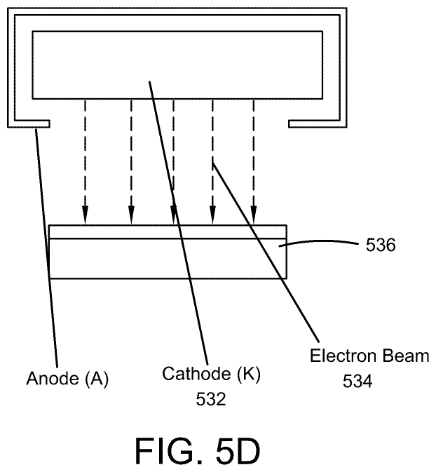

FIG. 3 illustrates a schematic view of High-Power Plasma Electron Beam Installation (HPPEBI) system in accordance with the disclosed structure. For generating plasma, a high voltage (>10 kV) is applied between a cathode 302 and an anode 304. The plasma contains high-energy electrons, ions, and neutral atoms. As described earlier, electrons are emitted perpendicular to the cathode surface, for providing consistent and focused energy delivery to the target. Electrons possess uniform energy levels and enable predictable and controlled interactions with a target material 306. As illustrated in FIGS. 5A-5D, cathode 302 in different embodiments can have different geometry for configuring electron beams in different orientations.

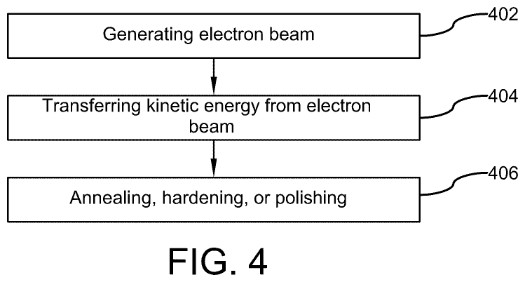

FIG. 4 illustrates a flow chart depicting a process of making structural changes in a target material using electron beam in accordance with one embodiment of the present invention. Initially, an electronic beam is generated from the cathode and is projected towards the target material (Step 402). Then, the electrons of the beam collide with atoms in the target material and transfer kinetic energy stored therein for causing localized melting, evaporation, or surface restructuring (Step 404). In some embodiments, annealing, hardening, or polishing can be performed with high precision, leaving the bulk of the target material unaffected (Step 406).

In different embodiments, the beam can eject electrons from the target, leading to ionization and can be used for etching and deposition. When high-energy electrons displace atoms in the target material, vacancies or interstitial defects are created in the target material and can be used for strengthening metals, enhancing ceramic properties, or modifying semiconductor conductivity. High-energy electron beams can also induce phase transformations such as converting amorphous materials to crystalline structures.

It should be noted that High Power Plasma Electron Beam Installation (HPPEBI) system provides direct energy transfer from the electron beam to the target piece, thereby eliminating intermediate heating steps and maximizing efficiency and precision. Further, the electron beam targets specific areas with minimal impact on surrounding material.

FIG. 5A illustrates an exemplary HPPEBI system with a rectangular cathode in accordance with the disclosed structure. The cathode 502 is rectangular in shape (i.e., rectilinear) and provide a cylindrical heating focus area 506 on a workpiece 508. The electron beam 510 is rectilinear and provides uniform heating across cylindrical focus area 506. The cathode 502 is positioned with corresponding rectilinear anode 511a or 511b circumscribing their respective cathodes 502.

FIG. 5B illustrates another HPPEBI system with a doughnut-shaped (i.e., curvilinear) cathode in accordance with the disclosed structure. As illustrated, the cathode 512 is doughnut-shaped (i.e., curvilinear) and provides a converging electron beam 516 which converges at the workpiece 518 to form a circular or localized weld 520.

FIG. 5C illustrates another embodiment of the HPPEBI system in accordance with the disclosed structure. In the present embodiment, the cathode 522 is in the form of a spherical cap and provides a converging electron beam 526 for generating spot-heating at a spot 528 in the material 530. The cathode 522 can also be used for precise micro-welding.

FIG. 5D illustrates the HPPEBI system with rectangular prism cathode in accordance with the disclosed structure. As illustrated, the cathode 532 is in the form of a rectangular prism and provides a uniform linear electron beam 534 which uniformly heats a target material 536. The linear heat treatment is provided by the electron beam 534 and can also be used for surface polishing.

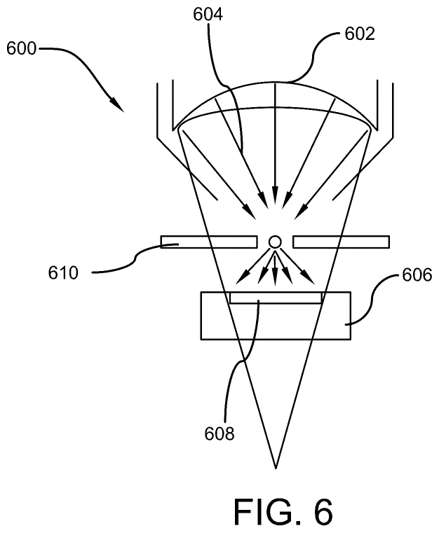

FIG. 6 illustrates yet another embodiment of HPPEBI system for thin film deposition in accordance with the disclosed structure. As illustrated, system 600 includes a cathode 602 which can have various curvature to project the electron beam 604. The electron beam 604 is projected on a crucible 606 and melts the metal in the crucible for forming melted area 608. The system 600 includes a diaphragm 610 to limit the focus of the electron beam 604 to a spot and to melt the metal 608 from crucible 606.

Certain terms are used throughout the following description and claims to refer to particular features or components. As one skilled in the art will appreciate, different persons may refer to the same feature or component by different names. This document does not intend to distinguish between components or features that differ in name but not structure or function. As used herein “high power plasma electron beam installation”, “advanced high energy plasma electron beam system”, “HPPEBI system”, and “system” are interchangeable and refer to the high-power plasma electron beam installation system 100 of the present invention.

Notwithstanding the forgoing, the high-power plasma electron beam installation system 100 of the present invention can be of any suitable configuration as is known in the art without affecting the overall concept of the invention, provided that it accomplishes the above stated objectives. One of the ordinary skill in the art will appreciate that the high-power plasma electron beam installation system 100 as shown in the FIGS. are for illustrative purposes only, and that many other configurations of the high-power plasma electron beam installation system 100 are well within the scope of the present disclosure. Although the dimensions of the high-power plasma electron beam installation system 100 are important design parameters for user convenience, the high-power plasma electron beam installation system 100 may be of any size that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A HPPEBI system comprising
a spherical cap cathode;
an electron beam;
a metal crucible;
a metal;
a first anode; and
a second anode;
wherein said spherical cap cathode having a circular focus of said electron beam;
wherein said metal crucible containing said metal; and
further wherein said electron beam focused on said metal crucible for heating said metal to its melting point.

2. The HPPEBI system of claim 1, wherein said second anode having a cooling water source.

3. The HPPEBI system of claim 1 further comprising a vacuum chamber, wherein said vacuum chamber holds a thin film deposition of an evaporated said metal.

4. The HPPEBI system of claim 1 further comprising a mold, wherein the melted said metal is poured into said mold.

5. The HPPEBI system of claim 4, wherein said electron beam aligned with a welded end of a first workpiece pipe.

6. The HPPEBI system of claim 5, wherein another electron beam aligned with another welded end of a second workpiece pipe.

7. The HPPEBI system of claim 5, wherein said electron beam directed orthogonally to said spherical cap cathode.

8. The HPPEBI system of claim 7, wherein said another electron beam directed orthogonally to another spherical cap cathode.

9. The HPPEBI system of claim 7, wherein said welded end is a circular zone of said first workpiece pipe.

10. The HPPEBI system of claim 9, wherein said another welded end is another circular zone of said second workpiece pipe.

11. A HPPEBI system comprising
a cathode;
an electron beam;
a metal crucible;
a metal;
a first anode; and
a second anode;
wherein said cathode having a circular focus of said electron beam;
wherein said metal crucible containing said metal;
wherein said electron beam focused on said metal crucible for heating said metal to its melting point; and
further wherein a water cooling system coupled to said cathode.

12. The HPPEBI system of claim 11 further comprising a vacuum chamber, wherein said vacuum chamber holds a thin film deposition of an evaporated said metal.

13. The HPPEBI system of claim 12 further comprising a mold, wherein the melted said metal is poured into said mold.

14. The HPPEBI system of claim 13, wherein said cathode having a curvilinear shape.

15. The HPPEBI system of claim 14, wherein said electron beam aligned with a welded end of a first workpiece pipe.

16. The HPPEBI system of claim 15, wherein said electron beam aligned with another welded end of a second workpiece pipe.

17. The HPPEBI system of claim 16, wherein said electron beam directed orthogonally to said cathode.

18. A HPPEBI system comprising
a rectilinear cathode;
an electron beam;
a workpiece;
a first rectilinear anode; and
a second rectilinear anode;
wherein said rectilinear cathode forming a cylindrical focus of said electron beam on said workpiece;
wherein said first rectilinear anode circumscribing said rectilinear cathode;
wherein said second rectilinear anode circumscribing said rectilinear cathode; and
further wherein said electron beam cylindrically focused on said workpiece.

19. The HPPEBI system of claim 18, wherein said electron beam is rectilinear.

20. The HPPEBI system of claim 18, wherein said electron beam directed orthogonally to said cathode.
